(19) United States
(12) Patent Application Publication
(10) Pub. No.: US 2015/0163942 A1
(43) Pub. Date: Jun. 11, 2015

(54) ACTIVE DEVICE ARRAY SUBSTRATE AND DISPLAY PANEL

(71) Applicant: Au Optronics Corporation, Hsinchu (TW)

(72) Inventor: Yen-Feng Wu, New Taipei City (TW)

(73) Assignee: Au Optronics Corporation, Hsinchu (TW)

(21) Appl. No.: 14/178,306

(22) Filed: Feb. 12, 2014

(30) Foreign Application Priority Data
Dec. 6, 2013 (TW) 102144883

(51) Int. Cl. H05K 7/06

(52) U.S. Cl. CPC H05K 7/06

(57) ABSTRACT

An active device array substrate including a substrate, a first and a second gate driving chips, pixels, first signal lines and a gate voltage supply line is provided. The first and second gate driving chips neighbor with each other and respectively have at least two first bonding pads and first output pad. The pixels are disposed in the display region. The first signal lines are connected to the pixels and the first output pads. The gate voltage supply line is disposed on the periphery circuit region. No conductive line is disposed between a side of the gate voltage supply line away from the pixels and an edge of the substrate. Each of the first and second gate driving chips is overlapped with at least a portion of the gate voltage supply line such that the first and second gate driving chips are bonded to the gate voltage supply line.

### CROSS-REFERENCE TO RELATED APPLICATION

This application claims the priority benefit of Taiwan application serial no. 102144883, filed on Dec. 6, 2013. The entirety of the above-mentioned patent application is hereby incorporated by reference herein and made a part of this specification.

### BACKGROUND

1. Technical Field

The disclosure relates to an active device array substrate and a display panel. Particularly, the disclosure relates to an active device array substrate with gate driving chips attached on substrate (COS) and a display panel using the same.

2. Related Art

Along with development of photoelectric technology and semiconductor technology, display panels are quickly developed. In various displays, flat displays have been widely used recently to replace cathode ray tube (CRT) displays to become a mainstream of next-generation displays. Taking a liquid crystal display (LCD) panel as an example, the LCD panel is mainly composed of an active device array substrate, an opposite substrate and a display medium layer disposed between the active device array substrate and the opposite substrate, where the active device array substrate has a plurality of pixels arranged in an array, and each of the pixels includes an active device and a pixel electrode electrically connected to the active device.

In order to achieve an aesthetic effect in appearance and a special visual experience, a current trend is to make the display panel to cope with a design requirement of slim border. However, as users have higher demand on image quality, image resolution becomes higher, and conductive lines disposed in a periphery circuit region are increased, and it is difficult to achieve the design requirement of slim border. Therefore, how to achieve both of the design requirement of slim border and a high display image quality is a goal anxiously pursued by related practitioners.

### SUMMARY

The disclosure is directed to an active device array substrate and a display panel, where gate driving chips are overlapped with a gate voltage supply line to achieve a design requirement of slim border and meanwhile improve a display image quality.

The disclosure provides an active device array substrate including a substrate, a first gate driving chip and a second gate driving chip, a plurality of pixels, a plurality of first signal lines and a gate voltage supply line. The substrate has a display region and a periphery circuit region adjacent to the display region. The first gate driving chip and the second gate driving chip are disposed in the periphery circuit region and neighbor with each other, and the first gate driving chip and the second gate driving chip respectively include at least two first bonding pads and a plurality of first output pads. The pixels are disposed in the display region. The first signal lines are disposed on the substrate, where one end of each of the first signal lines is connected to each of the pixels and the other end of each of the first signal lines is connected to each of the first output pads. The gate voltage supply line is disposed on the periphery circuit region of the substrate, where the gate voltage supply line extends to pass through the underneath of each of the first gate driving chip and the second gate driving chip, and no conductive line is disposed between a side of the gate voltage supply line away from the pixels and an edge of the substrate. Each of the first gate driving chip and the second gate driving chip is disposed on the gate voltage supply line, and each of the first gate driving chip and the second gate driving chip is overlapped with at least a portion of the gate voltage supply line such that the first bonding pads of each of the first gate driving chip and the second gate driving chip are bonded to the gate voltage supply line.

According to the above descriptions, the active device array substrate of the disclosure basically includes a plurality of pixels located in the display region and a plurality of gate driving chips located in the periphery circuit region, and the gate driving chips are overlapped with a same gate voltage supply line. Moreover, no conductive line is disposed between a side of the gate voltage supply line away from the pixels and an edge of the substrate, such that at least the design requirement of slim border (narrow border) is achieved, and meanwhile display image quality is improved.

In order to make the aforementioned and other features and advantages of the disclosure comprehensible, several exemplary embodiments accompanied with figures are described in detail below.

### BRIEF DESCRIPTION OF THE DRAWINGS

The accompanying drawings are included to provide a further understanding of the disclosure, and are incorporated in and constitute a part of this specification. The drawings illustrate embodiments of the invention and, together with the description, serve to explain the principles of the disclosure.

FIG. 1 is a top view of an active device array substrate according to an embodiment of the disclosure.

FIG. 2 is an enlarged view of a region M of FIG. 1.

FIG. 3 is a structural schematic diagram of gate driving chips of FIG. 2.

FIG. 4 is an enlarged view of a region N of FIG. 1.

FIG. 5A is a partial top view of an active device array substrate according to another embodiment of the disclosure.

FIG. 5B is a partial top view of an active device array substrate according to another embodiment of the disclosure.

FIG. 5C is a partial top view of an active device array substrate according to another embodiment of the disclosure.

FIG. 5D is a partial top view of an active device array substrate according to another embodiment of the disclosure.

FIG. 6 is a cross-sectional view of a display panel according to an embodiment of the disclosure.

### DETAILED DESCRIPTION OF DISCLOSED EMBODIMENTS

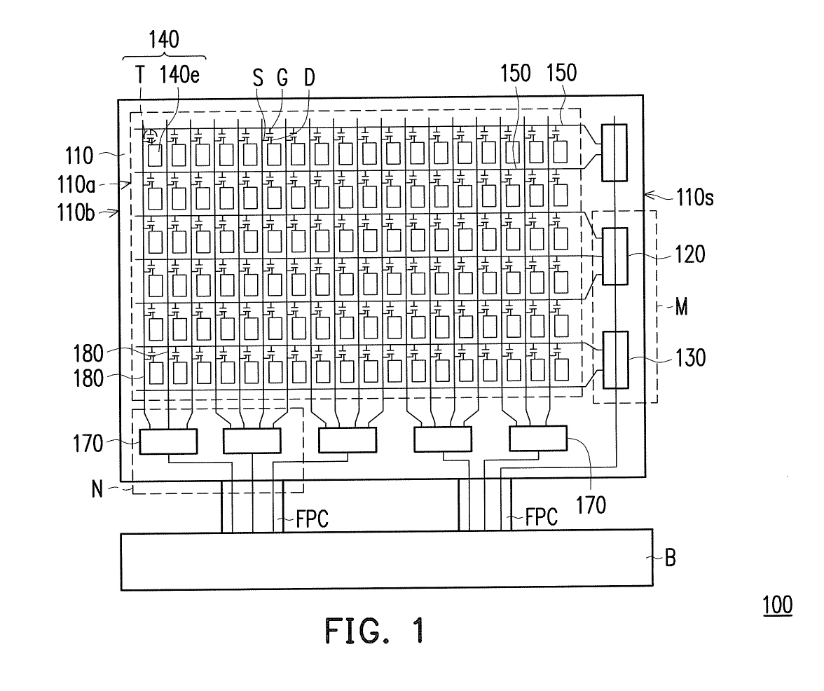

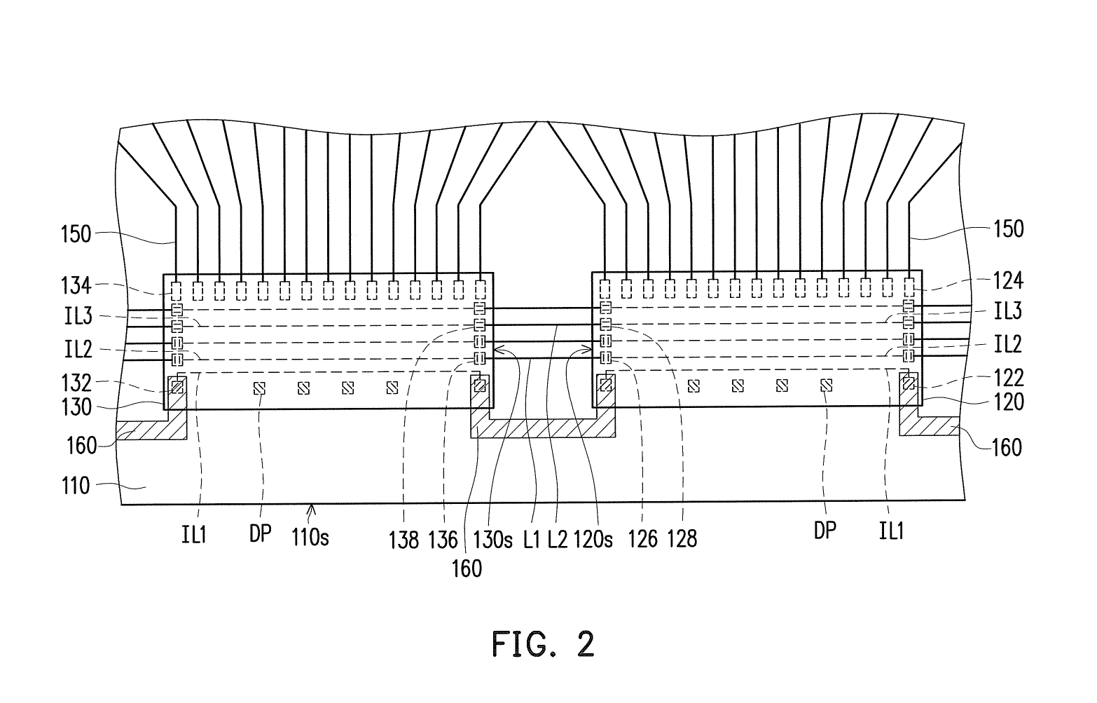

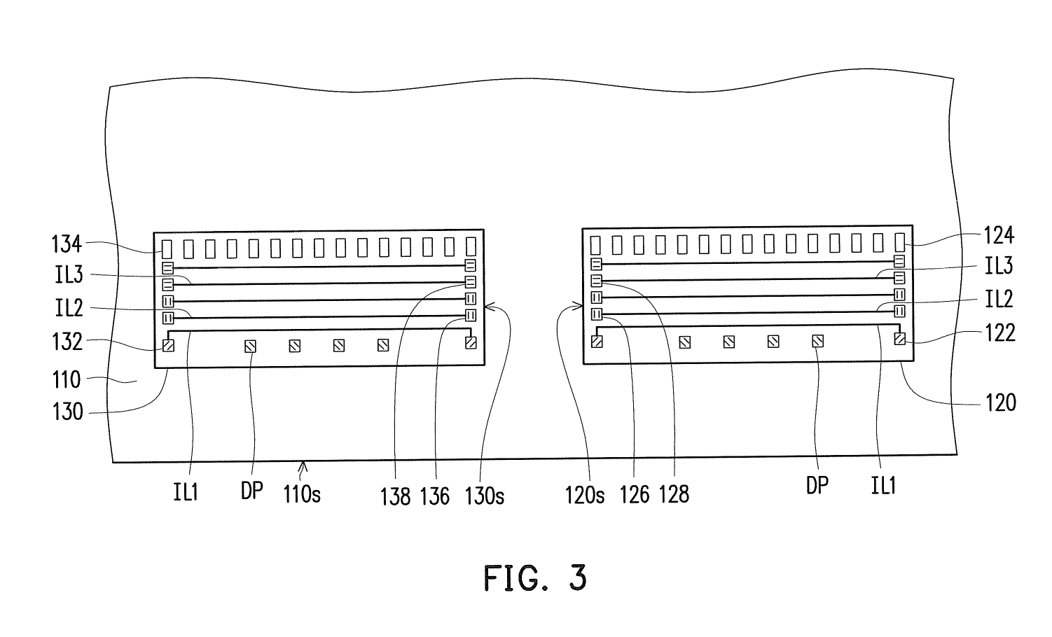

FIG. 1 is a top view of an active device array substrate according to an embodiment of the disclosure. FIG. 2 is an enlarged view of a region M of FIG. 1. FIG. 3 is a structural schematic diagram of gate driving chips of FIG. 2. Referring to FIG. 1, FIG. 2 and FIG. 3, the active device array substrate 100 includes a substrate 110, a plurality of gate driving chips connected in series, a plurality of pixels 140, a plurality of first signal lines 150 and a gate voltage supply line 160. The gate driving chips connected in series are, for example, a first gate driving chip 120 and a second gate driving chip 130, and the gate driving chips can also be referred to as scan (line) driver ICs. The active device array substrate 100 may include a plurality of source driving chips 170, and in the disclosure, at least one source driving chip 170 is taken as an example for descriptions, and the source driving chip can also be referred to as a data (line) driver IC. It should be noticed that a circuit layout of the active device array substrate 100, and a connection of the first gate driving chip 120 and the second gate driving chip 130 are also illustrated in FIG. 2, and in order to clearly describe configuration positions and a connection relationship thereof, members on or in inner of the first gate driving chip 120 and the second gate driving chip 130 are illustrated by dot lines in FIG. 2, and bonding pads selectively configured on the active device array substrate 100 corresponding to the gate driving chips are omitted, and configuration of the members on or in inner of the first gate driving chip 120 and the second gate driving chip 130 is as that shown in FIG. 3.

The substrate 110 has a display region 110a and a periphery circuit region 110b. The periphery circuit region 110b is adjacent to the display region 110a. The display region 110a is mainly used to configure display components, and the periphery circuit region 110b is mainly used to configure peripheral trace lines and a driving circuit used for driving the display components.

The first gate driving chip 120 and the second gate driving chip 130 are disposed in the periphery circuit region 110b of the substrate 110 and neighbor with each other. The first gate driving chip 120 includes at least two bonding pads 122 and a plurality of output pads 124. The second gate driving chip 130 includes at least two bonding pads 132 and a plurality of output pads 134. The first gate driving chip 120 and the second gate driving chip 130 are connected in series. Therefore, the bonding pads 122 and 132 can be referred to as first bonding pads, and the output pads 124 and 134 are referred to as first output pads and are respectively located on the first and second gate driving chips 120 and 130.

The pixels 140 are disposed in the display region 110a of the substrate 110. Each of the pixels 140 includes an active device T and a pixel electrode 140e. The active device T is, for example, a thin-film transistor, and at least includes a gate G, a source S, a drain D and a semiconductor layer. Further, the active device T can be a bottom gate type thin-film transistor, a top gate type thin-film transistor, a stereography (3D) type thin-film transistor, a multi-gate type thin-film transistor or other suitable types of the thin-film transistor. Moreover, a material of the semiconductor layer includes amorphous silicon, polycrystalline silicon, microcrystalline silicon, monocrystalline silicon, nanocrystalline silicon, organic semiconductors, metal oxide semiconductors, carbon nanotubes, other suitable semiconductor materials or any combination of the above materials.

For example, each of the pixels 140 can be electrically connected to the corresponding first signal line 150 and a corresponding second signal line 180, where the pixel 140 can be electrically connected to the first signal line 150 through the gate of the active device T and electrically connected to the second signal line 180 through the source of the active device T. Now, the first signal line 150 can be referred to as a scan line or a gate line, and the second signal line 180 can be referred to as a data line or a source line. One end of each of the first signal lines 150 is connected to at least one of the pixels 140, and another end thereof is connected to either the output pad 120 of the first gate driving chip 120 or the output pad 130 of the second gate driving chip 130. A scan signal can be output to the first signal lines 150 through either the first gate driving chip 120 or the second gate driving chip 130 to sequentially drive the pixels 140.

The gate voltage supply line 160 is disposed on the periphery circuit region 110b of the substrate 110. The gate voltage supply line 160 extends to pass through the underneath of the first gate driving chip 120 and the second gate driving chip 130, and no conductive line is disposed between a side of the gate voltage supply line 160 away from the pixels 140 and an edge 110s of the substrate 110. In this way, a distribution area of the periphery circuit region 110b of the substrate 110 can be further decreased to achieve the design requirement of slim border.

In detail, the first gate driving chip 120 and the second gate driving chip 130 are all disposed on the gate voltage supply line 160, the first gate driving chip 120 is overlapped with at least a portion of the gate voltage supply line 160, and the second gate driving chip 130 is overlapped with at least a portion of the gate voltage supply line 160, such that the bonding pads 122 of the first gate driving chip 120 are bonded to (or namely connected to or namely attached to or namely joined to) the gate voltage supply line 160, and the bonding pads 132 of the second gate driving chip 130 are bonded to the gate voltage supply line 160. In detail, the gate voltage supply line 160 includes a plurality of discontinuous line segments, i.e., a plurality of interrupted line segments, and both of the first gate driving chip 120 and the second gate driving chip 130 have an inner connection line IL1 in inner thereof, and the inner connection lines IL1 are connected to the bonding pads 132, such that the line segments of the gate voltage supply line 160 are electrically connected to form a signal transmission line. In other words, the at least a portion of the gate voltage supply line 160 includes the discontinuous line segments is existed in the substrate 110, but the at least a portion of the gate voltage supply line 160 is not existed on the first gate driving chip 120 and the second gate driving chip 130, and the inner connection lines IL1 are respectively existed in the first gate driving chip 120 and the second gate driving chip 130, but the inner connection lines IL1 are not existed on the substrate 110. The gate voltage supply line 160, for example, transmits a gate turn on voltage, for example, a high-level gate voltage (such as VGH or VGG) or other suitable voltages to the first gate driving chip 120 and the second gate driving chip 130.

In detail, the gate voltage supply line 160 can be electrically connected to a circuit connection structure FPC, which is, for example, a flexible printed circuit board. Moreover, in an embodiment, the circuit connection structure FPC can be selectively connected to a control part B, where the control part B is, for example, configured with a timing controller, a common voltage controller, a polarity voltage converter, etc. In the present embodiment, the circuit connection structure FPC is not disposed at the edge 110s of the substrate 110 close to the first gate driving chip 120 and the second gate driving chip 130, but is disposed at a place close to the source driving chip 170, as that shown in FIG. 1.

The active device array substrate 100 further includes at least one first connection line L1, which is disposed on the periphery circuit region 110b of the substrate 110. In other words, the first connection line L1 is not formed on the first and second gate driving chips 120 and 130. The first connection line L1 is located between the first gate driving chip 120 and the second gate driving chip 130 neighboring with each other. The first gate driving chip 120 has a first side edge 120s, and the second gate driving chip 130 has a second side edge 130s, where the first side edge 120s and the second side edge 130s are opposite to (or namely face to) and separated from each other. Wherein, the first side edge can also be referred to as first edge of first gate driving chip or namely first side of first gate driving chip or namely edge in the first side of first gate driving chip, and the second side edge can also be referred to as second edge of second gate driving chip or namely second side of second gate driving chip or namely edge in the second side of second gate driving chip. The first gate driving chip 120 further includes at least one bonding pad 126. The bonding pad 126 is located at the first side edge 120s. The second gate driving chip 130 further includes at least one bonding pad 136, and the bonding pad 136 is located at the second side edge 130s. The bonding pads 126 and 136 can be referred to as second bonding pads, and the second bonding pads are respectively located on the first and second gate driving chips 120 and 130. One end of each of the first connection lines L1 is connected to the bonding pad 126, and the other end thereof is connected to the bonding pad 136. In other words, the first connection line L1 only extends to the first side edge 120s of the first gate driving chip 120 and the second side edge 130s of the second gate driving chip 130, and does not extend to a center position of the first gate driving chip 120 and a center position of the second gate driving chip 130. Therefore, an area of a part of the first connection line L1 overlapped to the first gate driving chip 120 is smaller than an area of the other part of the first connection line L1 that is not overlapped to the first gate driving chip 120, and an area of a part of the first connection line L1 overlapped to the second gate driving chip 130 is smaller than an area of the other part of the first connection line L1 that is not overlapped to the second gate driving chip 130.

In the present embodiment, a voltage transmitted by the first connection line L1 is smaller than a voltage transmitted by the gate voltage supply line 160. For example, the first connection line L1 can be used to transmit at least one type of voltage, for example, a ground voltage (Vground), a common voltage (Vcom), a low-level gate voltage (such as Vss/VGL/Vcc), a reference voltage, a constant voltage/current, or other suitable voltages. The first connection line L1 is disposed between the first signal line 150 and the gate voltage supply line 160. Moreover, the first gate driving chip 120 and the second gate driving chip 130 respectively include at least one inner connection line IL2. In other words, the inner connection line IL2 is not formed in the substrate 110, but is respectively existed in the first gate driving chip 120 and in the second gate driving chip 130. In the first gate driving chip 120, the inner connection line IL2 is connected to the bonding pad 126. In the second gate driving chip 130, the inner connection line IL2 is connected to the bonding pad 136. The voltage to be transmitted is, for example, first transmitted to the inner connection line IL2 in the second gate driving chip 130, and is further transmitted to the first connection line L1. Thereafter, the voltage is transmitted to the inner connection line IL2 in the first gate driving chip 120. In this way, the voltage to be transmitted is sequentially transmitted to the second gate driving chip 130 and the first gate driving chip 120 or is sequentially transmitted to the first gate driving chip 120 and the second gate driving chip 130.

The active device array substrate 100 further includes at least one second connection line L2 disposed on the periphery circuit region 110b of the substrate 110. In other words, the second connection line L2 is not formed in the first and second gate driving chips 120 and 130, but is existed in the substrate 110. The second connection line L2 is located between the first gate driving chip 120 and the second gate driving chip 130 neighboring with each other. The first gate driving chip 120 further includes at least one signal pad 128. The signal pad 128 is located at the first side edge 120s. The second gate driving chip 130 further includes at least one signal pad 138. The signal pad 138 is located at the second side edge 130s. The second connection line L2 and the signal pads 128 and 138 connected thereto transmit at least one type of signal, for example, a clock signal (Xck), a select signal (Vselect) or other suitable signals. In other words, the signal transmitted by the second connection line L2 and the signal pads 128 and 138 connected thereto is different to the signals/voltages transmitted by the gate voltage supply line 160, and the first connection line L1 and the bonding pads connected thereto. One end of each of the second connection lines L2 is connected to the signal pad 128, and the other end thereof is connected to the signal pad 138. In other words, the second connection line only extends to the first side edge 120s of the first gate driving chip 120 and the second side edge 130s of the second gate driving chip 130, and does not extend to a center position of the first gate driving chip 120 and a center position of the second gate driving chip 130. Therefore, an area of a part of the second connection line L2 overlapped to the first gate driving chip 120 is smaller than an area of the other part of the second connection line L2 that is not overlapped to the first gate driving chip 120, and an area of a part of the second connection line L2 overlapped to the second gate driving chip 130 is smaller than an area of the other part of the second connection line L2 that is not overlapped to the second gate driving chip 130.

The second connection line L2 is disposed between the first signal line 150 and the first connection line L1, i.e. the above three lines are not connected to each other. Moreover, the first gate driving chip 120 and the second gate driving chip 130 further include at least one inner connection line IL3, respectively. In other words, the inner connection line IL3 is not formed in the substrate 110, but is respectively existed in the first gate driving chip 120 and the second gate driving chip 130. In the first gate driving chip 120, the inner connection line IL3 is connected to the bonding pad 128. In the second gate driving chip 130, the inner connection line IL3 is connected to the bonding pad 138. The voltage to be transmitted is, for example, first transmitted to the inner connection line IL3 in the second gate driving chip 130, and is further transmitted to the second connection line L2. Thereafter, the voltage is transmitted to the inner connection line IL3 in the first gate driving chip 120. In this way, the voltage to be transmitted is sequentially transmitted to the second gate driving chip 130 and the first gate driving chip 120 or is sequentially transmitted to the first gate driving chip 120 and the second gate driving chip 130.

In the present embodiment, the first gate driving chip 120 may include a plurality of dummy pads DP, and the second gate driving chip 130 may also include a plurality of dummy pads DP. The dummy pads DP can also be referred to as redundant pads. The dummy pads DP can be used to balance a bonding stress of the first gate driving chip 120 when the first gate driving chip 120 is bonded to the substrate 110 and a bonding stress of the second gate driving chip 130 when the second gate driving chip 130 is bonded to the substrate 110, so as to improve bonding reliability of the first gate driving chip 120 and the second gate driving chip 130.

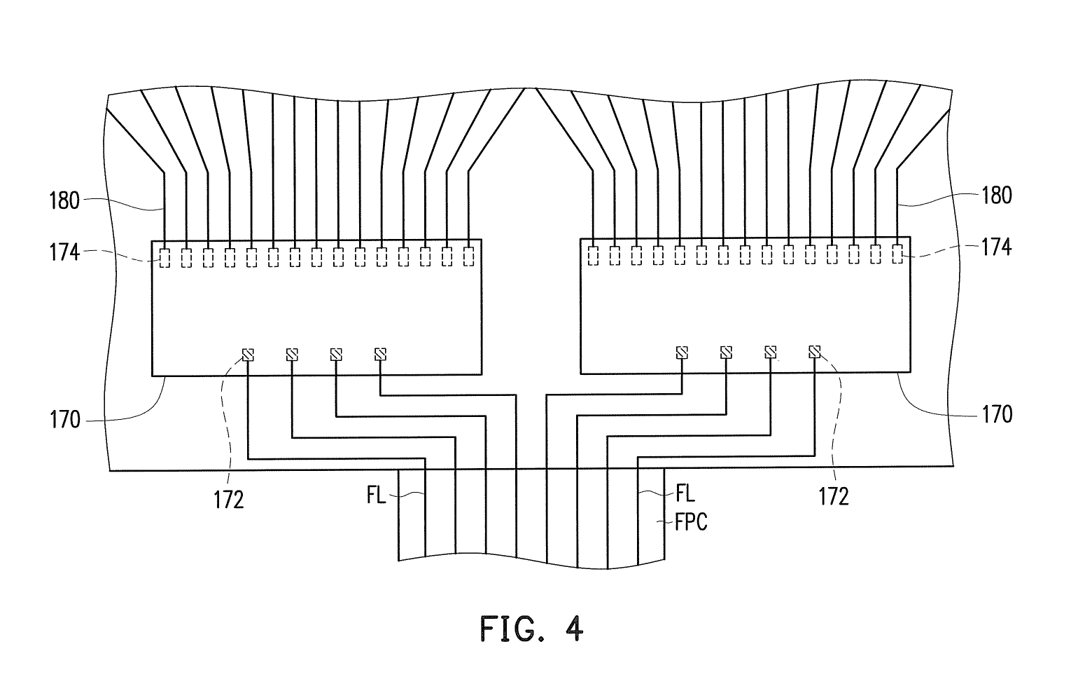

FIG. 4 is an enlarged view of a region N of FIG. 1. Referring to FIG. 1 and FIG. 4, the source driving chips 170 are disposed on the periphery circuit region 110b of the substrate 110. The source driving chips 170 can be selectively connected in series or not connected in series to each other. If the source driving chips 170 are selectively connected in series to each other, the aforementioned first connection line L1 and the related configuration thereof and the second connection line L2 and the related configuration thereof are required. The source driving chip 170 at least includes a plurality of bonding pads 172 and a plurality of output pads 174. The output pads 174 can be referred to as second output pads, and the bonding pads 172 can be referred to as the second bonding pads or third bonding pads. One end of each of the second signal lines 180 is connected to the pixels 140, and the other end thereof is connected to the output pad 174. A data signal can be output to the second signal lines 180 through the source driving chips 170, and can be sequentially written into the pixels 140. In other words, the aforementioned first signal lines 150 are, for example, scan lines, and the second signal lines 180 are, for example, data lines. The pixels 140, the first signal lines 150 and the second signal lines 180 construct a pixel array located in the display region 110a. A detailed design of the pixel array is well known by those skilled in the art, which is not repeated.

In the present embodiment, the circuit connection structures FPC is, for example, located at the edge of the substrate 110 configured with the source driving chip 170. Moreover, a plurality of transmission lines FL of the circuit connection structure FPC are electrically connected to the bonding pads 172. The source driving chip 170 and the gate driving chips (including the first gate driving chip 120 and the second gate driving chip 130) are disposed at different sides of the display region 110a, though the disclosure is not limited thereto. In other embodiments, the source driving chip and the gate driving chips can be disposed at the same side of the display region 110a, so as to downsize the periphery circuit region located at the other three sides of the display region 110a to implement the design requirement of slim border. Similarly, the source driving chip and the gate driving chips can be disposed at the same side of the display region 110a, and now the circuit connection structure FPC can be located at the edge of the substrate 110 configured with the source driving chip 170.

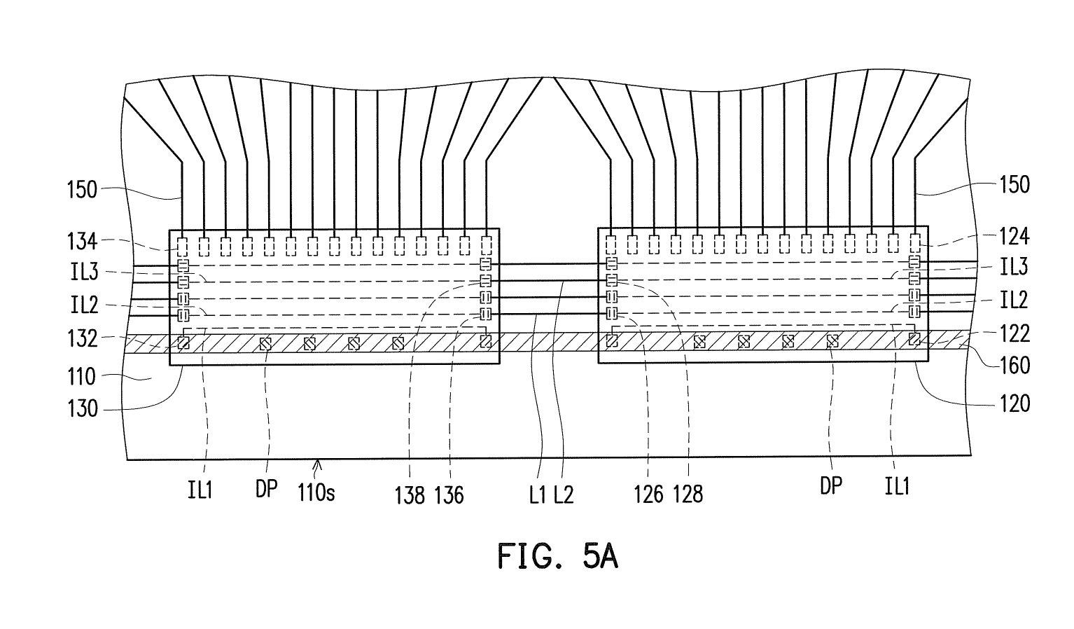

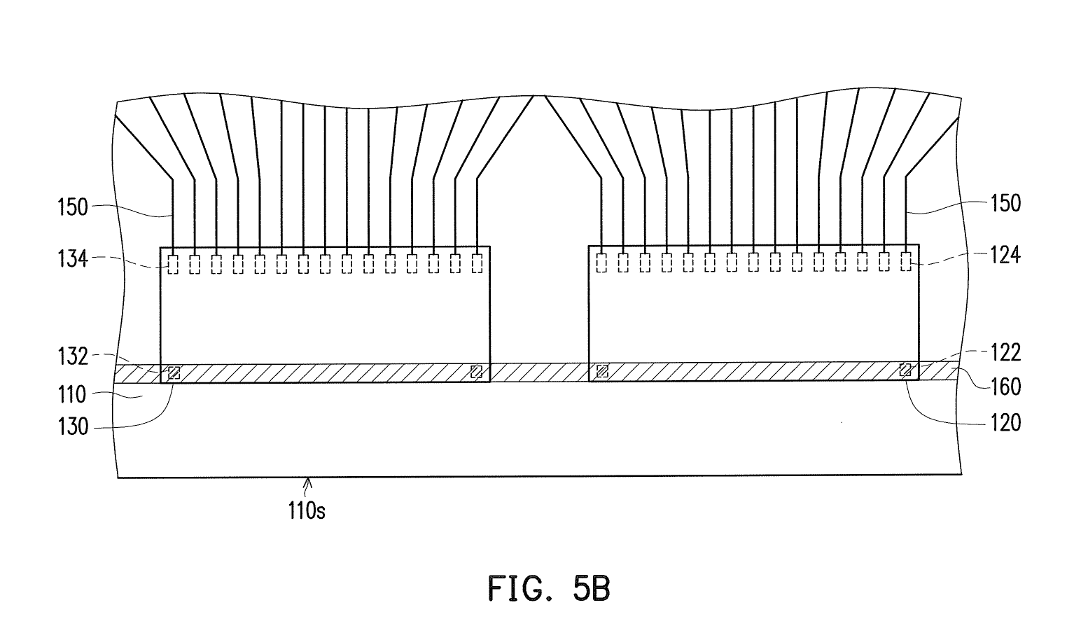

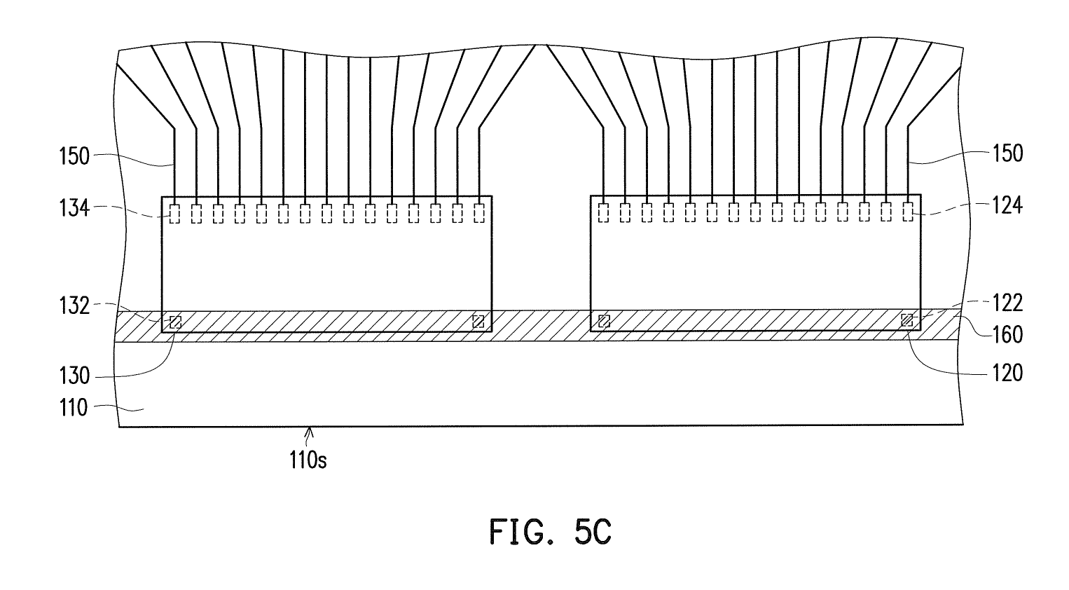

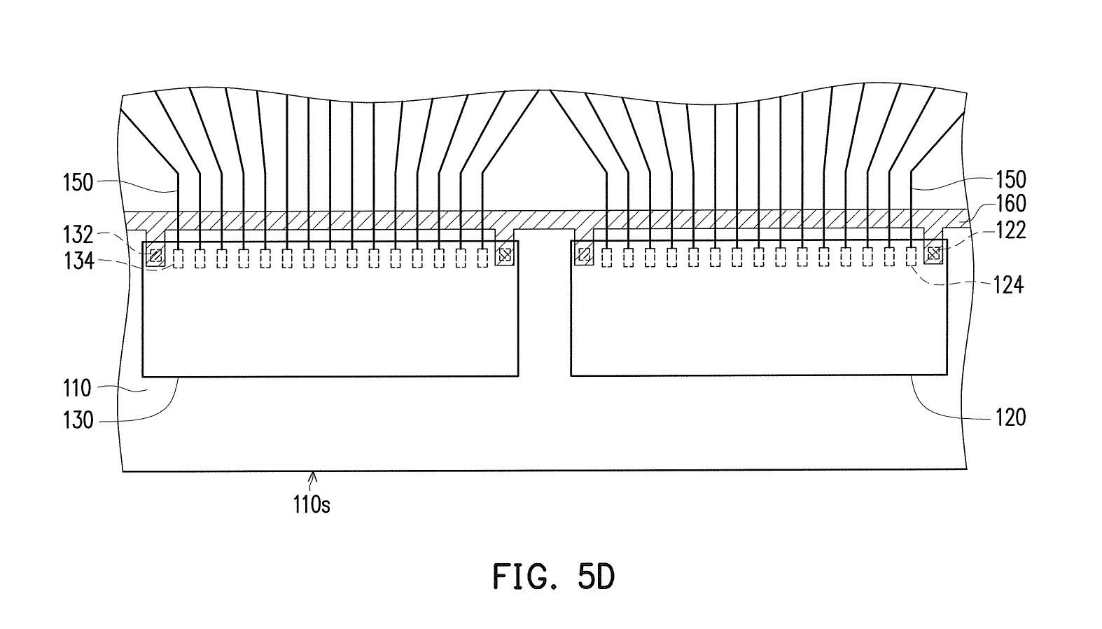

FIG. 5A is a partial top view of an active device array substrate according to another embodiment of the disclosure, which is, for example, another design of the region M of FIG. 2. The embodiment of FIG. 5A is similar to the embodiment of FIG. 2, and differences there between are as follows. In the present embodiment, the first gate driving chip 120 and the second gate driving chip 130 are completely overlapped with the gate voltage supply line 160 located under the first gate driving chip 120 and the second gate driving chip 130, such that the area of the periphery circuit region 110b from the first gate driving chip 120 and the second gate driving chip 130 to the edge 110s of the substrate 110 is further decreased. In other words, the gate voltage supply line 160 is not disposed between the display region 110a and the first gate driving chip 120 and the second gate driving chip 130, and the gate voltage supply line 160 is not overlapped with the first signal lines 150. Moreover, compared to the embodiment of FIG. 2 that the gate voltage supply line 160 includes a plurality of discontinuous line segments, i.e., a plurality of interrupted line segments, and the inner connection lines in the first and second gate driving chips 120 and 130 are used to form a connected line, in the embodiment of FIG. 5A, the gate voltage supply line 160 is a continuous line. Wherein the gate voltage supply line 160 is exited in the substrate 110, but is not existed in the first and second gate driving chips 120 and 130. Therefore, the gate voltage supply line 160 of FIG. 5A is not liable to be influenced by resistances of the interrupted line and the inner connection lines in the first and second gate driving chips 120 and 130 to cause a voltage drop phenomenon of the first and second gate driving chips 120 and 130, so as to provide a more stable voltage, such that gate turn-on voltages transmitted to the pixels 140 electrically connected to the first gate driving chip 120 and the pixels 140 electrically connected to the second gate driving chip 130 are maintained substantially the same, and the displayed image of the pixels 140 is not liable to be influenced by the voltage drop phenomenon to produce H-band, so as to effectively maintained the display quality.

In other embodiments, an edge of the gate voltage supply line 160 closest to the edge of the substrate 110 is substantially aligned to an edge of the first gate driving chip 120 closest to the edge of the substrate 110 and an edge of the second gate driving chip 130 closest to the edge of the substrate 110, as that shown in FIG. 5B. Alternatively, the edge of the gate voltage supply line 160 closest to the edge of the substrate 110 is exposed outside the edge of the first gate driving chip 120 closest to the edge of the substrate 110 and the edge of the second gate driving chip 130 closest to the edge of the substrate 110, as that shown in FIG. 5C. Therefore, according to FIG. 2 and FIG. 5A-5C, it is known that a distance between the gate voltage supply line 160 and the edge of the substrate 110 is h1, a distance between the first connection line L1 and the edge of the substrate 110 is h2, and a distance between the second connection line L2 and the edge of the substrate 110 is h3, where h1 is different to h2 and h3, and preferably, h1 is smaller than h2 or h3, where h2 is greater than h3 or h3 is greater than h2.

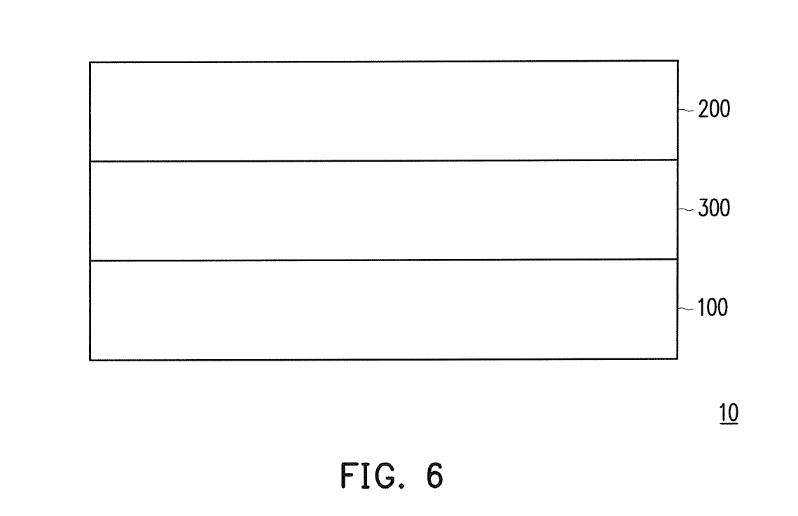

Moreover, in a varied embodiment, if the gate voltage supply line 160 is disposed between the display region 110a and the first gate driving chip 120 and the second gate driving chip 130, and a part of the gate voltage supply line 160 is overlapped with the first signal lines 150, i.e. the gate voltage supply line 160 crosses over the first signal lines 150 as that shown in FIG. 5D, although the area of the periphery circuit region 110b from the first gate driving chip 120 and the second gate driving chip 130 to the edge 110s of the substrate 110 is slightly decreased, since the voltage of the gate voltage supply line 160 may influence the signal transmitted by the first signal lines 150 and a display function of a display medium layer in the display region 110a (shown in FIG. 6), a display defect is produced, for example, mura or H-band, which decreases the quality of a displayed image. In FIG. 5B-5C, in order to clearly illustrate a configuration relationship of the gate voltage supply line 160, the first/second gate driving chip 120/130, the bonding pads 122/132, the first signal lines 150 and the output pads 124 and 134, other components and referential numbers thereof in FIG. 5A such as the inner connection lines, the first/second connection line, the signal pads, etc. are omitted. According to the above descriptions and comprehensive consideration, the embodiments of FIG. 5A-5C are the best embodiments, the embodiment of FIG. 2 is an exemplary embodiment, and the embodiment of FIG. 5D is a secondary exemplary embodiment.

The first gate driving chip 120 and the second gate driving chip 130 further has the inner connection lines IL1 therein. In other words, the inner connection lines IL1 are not formed in the substrate 110, but is existed in the first gate driving chip 120 and the second gate driving chip 130. The inner connection lines IL1 are connected to the bonding pads 132, and the bonding pads 132 are connected to the gate voltage supply line 160, where the gate voltage supply line 160 is an integral uninterrupted line (or a continuous line), and the inner connection lines IL1 and the gate voltage supply line 160 form a parallel structure.

Moreover, in the embodiment of FIG. 5A, the first gate driving chip 120 and the second gate driving chip 130 may include a plurality of dummy pads DP. The dummy pads can also be referred to as redundant pads. The dummy pads of the first gate driving chip 120 and the second gate driving chip 130 are bonded to the gate voltage supply line 160. The dummy pads DP can be used to balance a bonding stress of the first gate driving chip 120 when the first gate driving chip 120 is bonded to the substrate 110 and a bonding stress of the second gate driving chip 130 when the second gate driving chip 130 is bonded to the substrate 110, so as to improve bonding reliability of the first gate driving chip 120 and the second gate driving chip 130. Moreover, the first/second gate driving chip 120/130 of the aforementioned embodiments can be bonded to a corresponding line segment/pad on the substrate 110 through a bonding material (or namely attached material). The bonding material includes anisotropic conductive adhesive (ACA), anisotropic conductive film (ACF), isotropically conductive adhesive (ICA), isotropically conductive film (ICF), nonconductive adhesive (NCA), conductive welding material, or other suitable materials.

FIG. 6 is a cross-sectional view of a display panel according to an embodiment of the disclosure. Referring to FIG. 6, the display panel 10 includes an active device array substrate 100, an opposite substrate 200 and a display medium layer 300, where the display medium layer 300 is disposed between the active device array substrate 100 and the opposite substrate 200. A material of the display medium layer 300 includes a non-self-luminous medium (such as liquid crystal display medium, electrophoretic medium, electro-wetting medium, or other suitable medium), self-luminous medium (such as polymer organic light-emitting medium, small molecule organic light-emitting medium, inorganic luminescent medium, or other suitable medium), or other suitable display medium or a combination of the above media. Taking the liquid crystal display medium as an example, the liquid crystal display medium can be positive-type liquid crystal molecules, negative-type liquid crystal molecules, blue phase liquid crystal molecules, cholesterol liquid crystal molecules or other suitable liquid crystal molecules. The gate driving chips of the active device array substrate 100 may adopt the structure shown in FIG. 2 or FIG. 5. In this way, the display panel 10 satisfies the design requirement of slim border and meanwhile has a good display quality.

In summary, the active device array substrate of the disclosure basically includes a plurality of pixels located in the display region and a plurality of gate driving chips located in the periphery circuit region, and each of the first gate driving chip and the second gate driving chip is overlapped with at least a portion of the same gate voltage supply line. Moreover, no conductive line is disposed between a side of the gate voltage supply line away from the pixels and the fringe of the substrate, such that at least the design requirement of slim border is achieved.

It will be apparent to those skilled in the art that various modifications and variations can be made to the structure of the disclosure without departing from the scope or spirit of the disclosure. In view of the foregoing, it is intended that the invention cover modifications and variations of this invention provided they fall within the scope of the following claims and their equivalents.

What is claimed is:

1. An active device array substrate, comprising:
a substrate, having a display region and a periphery circuit region adjacent to the display region;
a first gate driving chip and a second gate driving chip, disposed in the periphery circuit region and neighboring with each other, wherein the first gate driving chip and the second gate driving chip respectively comprise at least two first bonding pads and a plurality of first output pads;
a plurality of pixels, disposed in the display region;
a plurality of first signal lines, disposed on the substrate, wherein one end of each of the first signal lines is connected to each of the pixels, and the other end of each of the first signal lines is connected to each of the first output pads; and
a gate voltage supply line, disposed on the periphery circuit region of the substrate, wherein the gate voltage supply line extends to pass through the underneath of each of the first gate driving chip and the second gate driving chip, and no conductive line is disposed between a side of the gate voltage supply line away from the pixels and an edge of the substrate, each of the first gate driving chip and the second gate driving chip is disposed on the gate voltage supply line, and each of the first gate driving chip and the second gate driving chip is overlapped with at least a portion of the gate voltage supply line such that the first bonding pads of each of the first gate driving chip and the second gate driving chip are bonded to the gate voltage supply line.

2. The active device array substrate of claim 1, further comprises:
at least one source driving chip, disposed in the periphery circuit region of the substrate, wherein the source driving chip comprises at least a plurality of second bonding pads and a plurality of second output pads; and
a plurality of second signal lines, disposed on the substrate, wherein one end of each of the second signal lines is connected to each of the pixels, and the other end of each of the second signal lines is connected to each of the second output pads.

3. The active device array substrate of claim 2, wherein a circuit connection structure is disposed at the edge of the substrate close to the at least one source driving chip, and a plurality of transmission lines of the circuit connection structure are electrically connected to the second bonding pads, respectively.

4. The active device array substrate of claim 1, further comprising a first connection line disposed on the periphery circuit region of the substrate, and located between the first gate driving chip and the second gate driving chip neighboring with each other, wherein
the first gate driving chip has a first side edge, and the second gate driving chip has a second side edge opposite to and separated from the first side edge, each of the first gate driving chip and the second gate driving chip further comprises at least one second bonding pad respectively located at the first side edge and the second side edge, one end of the first connection line is connected to the second bonding pad of the first gate driving chip, and the other end of the first connection line is connected to the second bonding pad of the second gate driving chip.

5. The active device array substrate of claim 4, wherein a voltage transmitted by the first connection line is smaller than a voltage transmitted by the gate voltage supply line.

6. The active device array substrate of claim 4, wherein the first connection line is disposed between the first signal lines and the gate voltage supply line.

7. The active device array substrate of claim 4, wherein the first connection line only extends to the first side edge of the first gate driving chip and the second side edge of the second gate driving chip, and does not extend to a center position of each of the first gate driving chip and the second gate driving chip.

8. The active device array substrate of claim 4, further comprising:
a second connection line, disposed on the periphery circuit region of the substrate, and located between the first gate driving chip and the second gate driving chip neighboring with each other, wherein
the first gate driving chip has a first side edge, and the second gate driving chip has a second side edge opposite to and separated from the first side edge, each of the first gate driving chip and the second gate driving chip further comprises at least one signal pad respectively located at the first side edge and the second side edge, one end of the second connection line is connected to the signal pad of the first gate driving chip, and the other end of the second connection line is connected to the signal pad of the second gate driving chip.

9. The active device array substrate of claim 8, wherein the second connection line is disposed between the first signal lines and the first connection line.

10. The active device array substrate of claim 8, wherein the second connection line only extends to the first side edge of the first gate driving chip and the second side edge of the second gate driving chip, and does not extend to a center position of each of the first gate driving chip and the second gate driving chip.

11. The active device array substrate of claim 8, wherein each of the first gate driving chip and the second gate driving chip further comprises a plurality of inner connection lines in inner thereof, and the inner connection lines are respectively connected to the second bonding pads and the signal pads.

12. The active device array substrate of claim 1, wherein each of the first gate driving chip and the second gate driving chip further comprises an inner connection line in inner thereof, and the inner connection line is connected between the first bonding pads.

13. The active device array substrate of claim 1, wherein no circuit connection structure is disposed at the edge of the substrate close to the first gate driving chip and the second gate driving chip.

14. The active device array substrate of claim 1, wherein each of the first gate driving chip and the second gate driving chip further comprises a plurality of dummy pads, and the dummy pads of each of the first gate driving chip and the second gate driving chip are bonded to the gate voltage supply line.

15. The active device array substrate of claim 1, wherein each of the first gate driving chip and the second gate driving chip is completely overlapped with the gate voltage supply line located under the first gate driving chip and the second gate driving chip.

16. A display panel, comprising:
the active device array substrate of claim 1;
an opposite substrate, corresponding to the active device array substrate; and
a display medium layer, disposed between the active device array substrate and the opposite substrate.
